(19) United States
(12) Patent Application Publication
(10) Pub. No.: US 2026/0085661 A1
(43) Pub. Date: Mar. 26, 2026

(54) Method, System, and Device for Wind Speed Prediction and Layout optimization in Wind Power Generation

(71) Applicant: Shanghai Investigation, Design & Research Institute Co., Ltd., Shanghai (CN)

(72) Inventors: Haoran XU, Shanghai (CN); Lin LIN, Shanghai (CN); Yifeng LIN, Shanghai (CN); Panpan SHEN, Shanghai (CN); Jie ZHANG, Shanghai (CN); Qingbin ZHU, Shanghai (CN); Shilun ZHAO, Shanghai (CN)

(73) Assignee: Shanghai Investigation, Design & Research Institute Co., Ltd., Shanghai (CN)

(21) Appl. No.: 19/309,641

(22) Filed: Aug. 26, 2025

(30) Foreign Application Priority Data
Sep. 23, 2024 (CN) 2024113259338

(51) Int. Cl. F03D 80/00; G06F 30/27; G06F 30/28

(52) U.S. Cl. CPC F03D 80/002; G06F 30/27; G06F 30/28

(57) ABSTRACT

A method, system, and device for wind speed prediction and layout optimization in wind power generation are provided. The method includes: obtaining a basic wind resource dataset of a target region; constructing a physics-informed neural network model based on the basic wind resource dataset; obtaining wind speeds data at a specific location in a velocity field based on the physics-informed neural networks and constructing a training dataset; training the physics-informed neural network model based on the training dataset; reconstructing a wind speed distribution within the velocity field and predicting wind speeds for a next time period with a wind farm using the trained physics-informed neural network model; and optimizing a layout of a wind turbine cluster based on a reconstructed wind speed distribution within the velocity field. The present application reconstructs a two-dimensional velocity field of the wind farm by training the PINN and enables accurate ultra-short-term wind speed prediction.

### FIELD OF THE INVENTION

The present application relates to the technical field of wind power prediction, and in particular, to a method, system, and device for wind speed prediction and layout optimization in wind power generation.

### BACKGROUND OF THE INVENTION

Wind energy is an inherently variable and unstable resource, exhibiting significant randomness, intermittency, and fluctuation, which often results in unstable wind power output. As the wind power industry continues to grow, the large-scale integration of wind energy into the power grid is expected to pose considerable challenges to the stability and reliability of the grid system.

Therefore, accurate prediction of wind farm power output, combined with the efficient regulation of wind turbine systems, is critical to maintaining the stability and reliability of the power grid.

In addition, minimizing various types of power losses during the operation of wind farms has become increasingly critical. Among these, the wake effect is one of the most significant factors affecting wind farm efficiency. The objective of optimizing the layout of wind turbines is to reduce wake interference between turbines as much as possible within a limited wind field, through appropriate turbine selection and positioning. Generally, larger row and column spacing between turbines leads to reduced wake effects and increased power output. However, increasing the spacing also directly impacts the overall layout scale of the wind farms.

In recent years, control strategies and layout optimization of wind farms have become key areas of research in the wind energy sector. With the rapid development of artificial neural network (ANN) technology, it has demonstrated significant advantages in time series prediction.

Furthermore, existing wind field modeling methods, such as computational fluid dynamics (CFD), can provide high simulation accuracy. However, due to the multiscale nature spanning from atmospheric scales to the boundary layer scales of wind turbine blades, these methods face significant modeling challenges and incur high computational costs.

Therefore, the existing wind farm modeling methods face significant challenges and high computational costs due to the multiscale nature spanning from atmospheric scales to the boundary layer scales of wind turbine blades. Additionally, technical issues such as insufficient accuracy in wind speed prediction for the wind farms remain unresolved.

### SUMMARY OF THE INVENTION

The present application provides a method, system and device for wind speed prediction and layout optimization in wind power generation to address the problems in the prior art, such as unstable wind power generation, large power generation losses in a power generation process of the wind farm, and multi-scale problems in existing modeling approaches, from atmospheric scale to wind turbine boundary layer, which result in excessive modeling complexity and computational cost, as well as insufficient accuracy in wind speed prediction.

A first embodiment of the present application provides a method for wind speed prediction and layout optimization in wind power generation. The method includes: obtaining a basic wind resource dataset of a target region including one or more of wind farm size, location information, wind speed, wind direction, temperature, air pressure, terrain, and water depth; constructing a physics-informed neural network model based on the basic wind resource dataset; obtaining wind speed data at a specific location in a velocity field based on the physics-informed neural network model and constructing a training dataset; training the physics-informed neural network model based on the training dataset; reconstructing a wind speed distribution within the velocity field and obtaining predicted wind speed data of a wind farm for a next time period using a trained physics-informed neural network model; and optimizing a layout of a wind turbine cluster based on a reconstructed wind speed distribution within the velocity field.

In an implementation of the first embodiment, a method for constructing the physics-informed neural network model based on the basic wind resource dataset includes steps of: extracting an actual wind farm size based on the basic wind resource dataset; defining a two-dimensional velocity field based on the actual wind farm size; designing a neural network architecture based on the two-dimensional velocity field; and constructing the physics-informed neural network model by incorporating physical constraints into a loss function of the neural network architecture for optimization.

In an implementation of the first embodiment, a method for incorporating the physical constraints into the loss function of the neural network architecture for optimization includes steps of: calculating partial derivatives of partial differential equations using automatic differentiation; integrating the physical constraints into the loss function of the neural network architecture using physical equations; and obtaining a total loss function by combining the partial derivatives of the partial differential equations with the loss function.

In an implementation of the first embodiment, the physical equations include two-dimensional Navier-Stokes equations, continuity equation, and turbulence model. The physical equations are calculated as follows:

$$\frac{\partial u}{\partial t} + u \frac{\partial u}{\partial x} + v \frac{\partial u}{\partial y} = - \frac{1}{ρ} \frac{\partial p}{\partial x} + v ( \frac{{\partial }^{2} u}{\partial {x}^{2}} + \frac{{\partial }^{2} u}{\partial {y}^{2}} ) \qquad ( 1 )$$

$$\frac{\partial v}{\partial t} + u \frac{\partial v}{\partial x} + v \frac{\partial v}{\partial y} = - \frac{1}{ρ} \frac{\partial p}{\partial y} + v ( \frac{{\partial }^{2} v}{\partial {x}^{2}} + \frac{{\partial }^{2} v}{\partial {y}^{2}} ) \qquad ( 2 )$$

$$\frac{\partial u}{\partial x} + \frac{\partial v}{\partial y} = 0 \qquad ( 3 )$$

where ρ denotes a fluid density; u, v denote measured velocity components of a fluid at a location (x, y) and a time t.

In an implementation of the first embodiment, the total loss function is calculated as follows:

$$L = {ω}_{1} {L}_{d} + {ω}_{2} {L}_{f} \qquad ( 4 )$$

$${L}_{d} = {u}_{MRMSE} + {v}_{MRMSE} \qquad ( 5 )$$

$${u}_{MRMSE} = \frac{1}{{N}_{T}} {\sum }_{i = 1}^{{N}_{t}} ( \sqrt{\frac{1}{n} {\sum }_{i = 1}^{n} {( {\hat{u}}_{i} ( t ) - {u}_{i} ( t ) )}^{2}} ) \qquad ( 6 )$$

$${v}_{MRMSE} = \frac{1}{{N}_{T}} {\sum }_{i = 1}^{{N}_{t}} ( \sqrt{\frac{1}{n} {\sum }_{i = 1}^{n} {( {\hat{v}}_{i} ( t ) - {v}_{i} ( t ) )}^{2}} ) \qquad ( 7 )$$

$${L}_{f} = \frac{1}{{N}_{f}} {\sum }_{i = 1}^{{N}_{f}} {\vert G ( {u}_{i} , {p}_{i} ) \vert}^{2} \qquad ( 8 )$$

where L denotes the total loss function; L_{d} denotes a data fitting loss term; L_{f} denotes a physics-based loss term, i.e., a PDE residual loss; ω₁ denotes a weight of a data item; ω₂ denotes a weight of a physics-based loss term; n denotes a total number of laser sensors; N_{T} denotes a total number of time steps; u, v denote measured velocity components of a fluid at a location (x, y) and a time t, i.e., measured values of the location; û, \hat{v} denote predicted velocity components of a fluid at a location (x, y) and a time t; MRMSE denotes an average root mean square error; and G denotes an implicit form of Navier-Stokes equations.

In an implementation of the first embodiment, a method for obtaining the wind speed data at the specific location in the velocity field based on the physics-informed neural network model, and constructing the training dataset includes steps of: determining a target research region of the wind farm and the specific location within the velocity field; obtaining the wind speed data at the specific location within the velocity field using laser sensors distributed throughout the wind farm; preprocessing the wind speed data collected from the specified location within the velocity field to generate preprocessed wind speed data at the specific location within the velocity field; dividing continuous time-series data into multiple fixed-length time windows; assigning a label to each of the time windows; and constructing a training dataset based on preprocessed wind speed data at the specified location within the velocity field and the label, and using the dataset as supervised points for model training.

In an implementation of the first embodiment, a method for training the physics-informed neural network model based on the training dataset includes steps of: performing a first training on the training dataset using an Adam optimizer to obtain a physics-informed neural network model with a reduced loss value; performing a second training using an L-BFGS optimizer until a convergence condition is satisfied, thereby obtaining the trained physics-informed neural network model.

In an implementation of the first embodiment, a method for reconstructing the wind speed distribution within the velocity field to obtain the predicted wind speed data of the wind farm for the next time period using the trained physics-informed neural network model includes steps of: inputting spatial coordinates of the velocity field as target points for wind speed reconstruction into the trained physics-informed neural network model to obtain the predicted wind speed data corresponding to the spatial coordinates of the velocity field; mapping the predicted wind speed data onto the grid of the velocity field to form a reconstructed wind speed distribution map; analyzing the reconstructed wind speed distribution map to obtain an analyzed wind speed distribution result, and performing optimization and fine-tuning on the trained physics-informed neural network model accordingly; acquiring real-time wind speed data at a target location in a given time period; preprocessing the real-time wind speed data in the given time period to obtain preprocessed real-time wind speed data; and inputting the preprocessed real-time wind speed data in the given time period into the trained physics-informed neural network model for prediction, thereby obtaining the predicted wind speed data for the next time period within the wind farm.

A second embodiment of the present application provides a system for wind speed prediction and layout optimization in wind power generation. The system includes an acquisition module, a model construction module, a wind speed acquisition module, a model training module, a wind speed reconstruction module, and a layout optimization module. The acquisition module obtains a basic wind resource dataset of a target region, including one or more of wind farm size, location information, wind speed, wind direction, temperature, air pressure, terrain, and water depth. The model construction module constructs a physics-informed neural network model based on the basic wind resource dataset. The wind speed acquisition module obtains wind speed data at a specific location in a velocity field based on the physics-informed neural network model, and constructs a training dataset. The model training module trains the physics-informed neural network model based on the training dataset. The wind speed reconstruction module reconstructs a wind speed distribution in the velocity field through a trained physics-informed neural network model, and obtains a predicted wind speed of a wind farm for a next time period. The layout optimization module optimizes a layout of a wind turbine cluster based on a reconstructed wind speed distribution within the velocity field.

A third embodiment of the present application provides a device for wind speed prediction and layout optimization in wind power generation. The device includes a processor and a memory. The memory is configured to store computer programs. The processor is connected to the memory and configured to execute the computer programs stored in the memory, thereby causing the device to perform each step of the method for wind speed prediction and layout optimization.

As described above, the method, system, and device for wind speed prediction and layout optimization of the present application have the following beneficial effects.

(1) The method for wind speed prediction and layout optimization of the present application adopts the physics-informed neural network model. By incorporating partial differential equations into an existing neural network, the model is constrained to follow physical laws, thereby addressing the limitations of existing neural networks that rely heavily on large volumes of data and often exhibit poor robustness, especially when dealing with incomplete or noisy datasets. Furthermore, the model leverages the prior knowledge of physical constraint equations that govern data generation, integrating them into the loss function as regularization terms. As a result, the model can accurately reconstruct regional flow characteristics even with a limited number of flow field sampling points. The model is well-suited for wind farm modeling, offering high-precision, ultra-short-term velocity field predictions while maintaining computational efficiency. This provides effective support for short-term control strategies such as pitch and yaw regulation, thereby ensuring the safe and stable operation of wind farms.

(2) The present application simulates the wind speed distribution within the velocity field by utilizing lidar sensors deployed throughout the wind farm. Based on measured data, the present application more accurately reflects actual operating conditions. It predicts wind speed changes at turbine locations in the next time period, providing a reference for analyzing wind power generation patterns and enabling a more comprehensive understanding of the wind farm's physical characteristics.

(3) The PINN demonstrates significant advantages in solving high-dimensional forward and inverse problems. By integrating machine learning techniques with extensive fluid dynamics data, the present application not only provides accurate predictions of the velocity field but also ensures high computational efficiency.

(4) The accuracy of wind farm evaluation can be enhanced by combining mesoscale data simulation from lidar-based wind measurements with microscale numerical simulation using the PINN.

(5) The present application is applicable to various scenarios, including offshore wind farms and onshore wind farms, demonstrating broad applicability.

### BRIEF DESCRIPTION OF DRAWINGS

FIG. 1 is a flowchart of a method for wind speed prediction and layout optimization in wind power generation according to an embodiment of the present application.

FIG. 2 is a flowchart of a wind speed prediction process of a method for wind speed prediction and layout optimization in wind power generation according to an embodiment of the present application.

FIG. 3 is a flowchart of step S2 in a method for wind speed prediction and layout optimization according to the present application.

FIG. 4 is a schematic diagram of a physics-informed neural network of a method for wind speed prediction and layout optimization according to an embodiment of the present application.

FIG. 5 is a flowchart of step S3 of a method for wind speed prediction and layout optimization in wind power generation according to the present application.

FIG. 6 is a flowchart of step S4 of a method for wind speed prediction and layout optimization in wind power generation according to the present application.

FIG. 7 is a flowchart of step S5 of a method for wind speed prediction and layout optimization in wind speed generation according to the present application.

FIG. 8 is a layout of laser sensors and wind turbines in a wind farm according to an embodiment of a wind speed prediction and layout optimization method of the present application.

FIG. 9 is a schematic structural diagram of a system for wind speed prediction and layout optimization according to an embodiment of the present application.

FIG. 10 is a schematic structural diagram of a device for wind speed prediction and layout optimization according to an embodiment of the present application.

### DESCRIPTION OF REFERENCE NUMERALS

91 Acquisition module
92 Model construction module
93 Wind speed acquisition module
94 Model training module
95 Wind speed reconstruction module
96 Layout optimization module
101 Processor
102 Memory

### DETAILED DESCRIPTION

The specific embodiments are described below to illustrate the implementation of the present application, and those skilled in the art can easily understand other advantages and effects of the present application from the content disclosed in this specification. The present application can also be implemented or applied in other specific embodiments. The details provided in this description can be modified or altered in various ways based on different perspectives and applications without departing from the spirit of the present application.

It should be noted that the embodiments and features of the embodiments in the present application can be combined with each other as long as there is no conflict. It should be noted that the illustrations provided in the following embodiments are merely schematic representations to explain the basic concepts of this application. Therefore, the figures only show components related to this application and are not drawn according to the actual number, shape, and size of components in practice. The actual implementation may involve variations in the type, quantity, and proportions of the components, and the layout of the components could be more complex.

A method, system, and device for wind speed prediction and layout optimization in wind power generation, as disclosed in the embodiments of the present application, will be described in detail below with reference to the accompanying drawings.

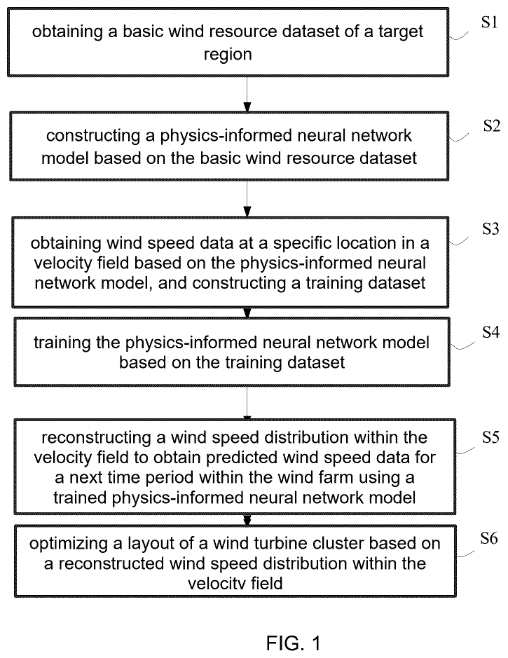

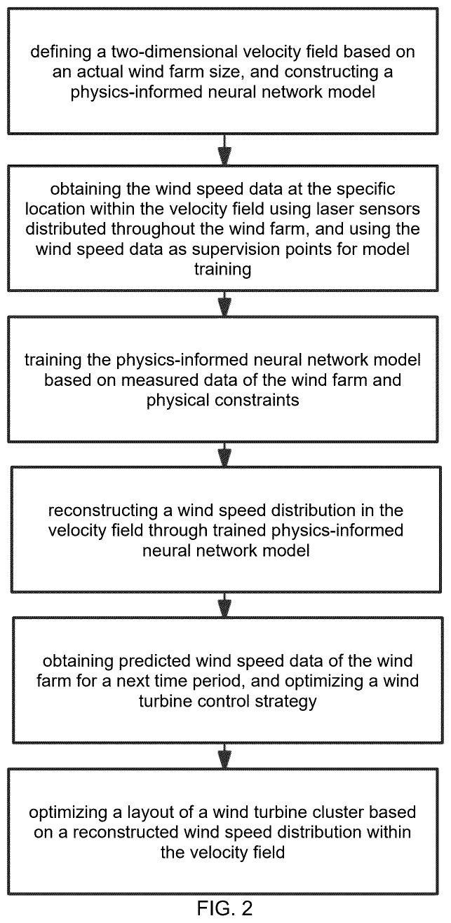

Please refer to FIG. 1 and FIG. 2. FIG. 1 is a flowchart of a method for wind speed prediction and layout optimization in wind power generation according to an embodiment of the present application. FIG. 2 is a flowchart of a wind speed prediction process of a method for wind speed prediction and layout optimization in wind power generation according to an embodiment of the present application. As shown in FIGS. 1 and 2, a method for wind speed prediction and layout optimization in wind power generation is provided.

The method for wind speed prediction and layout optimization in wind power generation specifically includes the following steps.

S1, obtaining a basic wind resource dataset of a target region, including but not limited to various types of data such as wind farm size, location information, wind speed, wind direction, temperature, air pressure, terrain, and water depth.

In this embodiment, based on research needs, various types of data and information within a wind farm are collected from the target region, including location information, meteorological data, terrain data, and the like.

Specifically, a scope of the target region for data acquisition is first determined. Then, data sources are identified, such as official or authoritative organizations (such as national or local government energy departments, meteorological bureaus, oceanographic institutes, research institutions, and commercial data providers), from which relevant data is obtained through their respective channels. Finally, the acquired data is collected, compiled, and organized.

For example, the specific location and scope of the wind farm from which data is to be acquired are first determined. Then, accurate location information (such as latitude and longitude) and approximate size of the wind farm are obtained through map services (such as Google Maps and Gaode Maps) or marine Geographic Information Systems (GIS). Subsequently, wind speed and wind direction data are acquired using data collection devices. For instance, real-time wind speed and direction data may be collected through field observation using buoys, meteorological towers, weather stations, and the like. Wind speed and direction data at broader spatial and longer temporal scales may be obtained using satellite remote sensing technology and numerical simulation methods. Alternatively, historical wind speed and direction datasets that have been processed and analyzed may be purchased from commercial data providers. In addition, meteorological data such as air temperature and air pressure for the target area may be obtained from meteorological bureaus or other relevant institutions to assist in analyzing the operating environment and performance of the wind farm. Furthermore, detailed measurements of seabed topography, such as water depth and submarine landforms, may be obtained using marine geological survey vessels, sonar equipment, or similar means. Finally, the collected data is integrated to form a complete basic wind resource dataset.

It should be noted that during a data collection process, the accuracy and reliability of the data must be ensured. Critical data should undergo multiple rounds of verification and cross-checking. Additionally, attention should be paid to the timeliness of the data, and the basic wind resource dataset should be promptly updated and maintained to reflect the most current conditions of the wind farm.

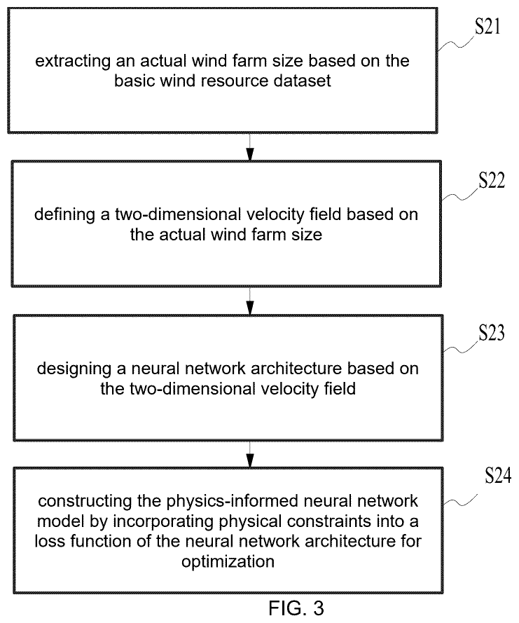

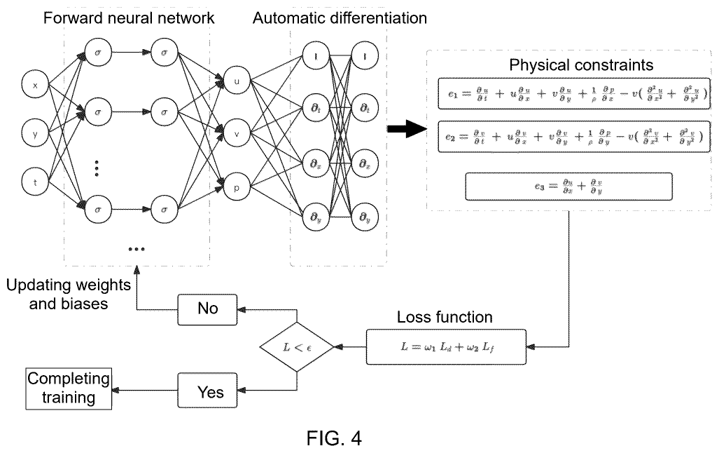

S2, constructing a physics-informed neural network model based on the basic wind resource dataset. Please refer to FIG. 3 and FIG. 4. FIG. 3 is a flowchart of step S2 of a method for wind speed prediction and layout optimization according to the present application. FIG. 4 is a schematic diagram of a physics-informed neural network of a method for wind speed prediction and layout optimization according to an embodiment of the present application. As shown in FIGS. 3 and 4, step S2 includes the following steps.

The present application adopts a Physics-Informed Neural Network (PINN) for modeling.

The PINN is a type of neural network architecture that employs a deep neural network as a nonlinear function approximator. By leveraging automatic differentiation, which is widely used in deep neural networks, the PINN incorporates a differential form of constraints in partial differential equations to be solved into a loss function of the deep neural network. Through this optimization process, a deep neural network model is trained to approximate the solutions of the partial differential equations under physical model constraints.

Sub-step S21, extracting an actual wind farm size based on the basic wind resource dataset.

Sub-step S22, defining a two-dimensional velocity field based on the actual wind farm size.

In this embodiment, wind speed data is selected from the basic wind resource dataset and preprocessed to obtain preprocessed wind speed data. In combination with a two-dimensional grid defined based on the actual wind farm size, a wind field is simulated using the two-dimensional grid to generate a two-dimensional velocity field.

Specifically, the wind speed data selected from the basic wind resource dataset should cover a whole wind farm area and span multiple temporal scales. The wind speed data should comprehensively reflect wind speed variations across different time scales within the wind farm area. Subsequently, the wind speed data is subjected to a cleaning process to remove outliers and noise. If necessary, interpolation may be performed to ensure the spatial completeness and continuity of the wind speed data across the wind farm area. Furthermore, wind field characteristics, specifically spatiotemporal variations of wind speed, including metrics such as mean wind speed, wind direction, and wind speed fluctuations, are analyzed to identify a prevailing wind direction and wind speed variation regions within the wind field. Finally, based on analysis results of the basic wind resource dataset, the two-dimensional grid is defined for simulating the wind field. A grid resolution should be determined in accordance with the research objectives and the required data precision, and should generally be fine enough to capture subtle variations within the wind field. At grid points, corresponding velocity values are assigned based on the processed wind speed data, thereby generating the two-dimensional velocity field.

Sub-step S23, designing a neural network architecture based on the two-dimensional velocity field.

Sub-step S24, constructing a physics-informed neural network model by incorporating physical constraints into a loss function of the neural network architecture for optimization. Specifically, the sub-step S24 includes the following steps: first, partial derivatives of partial differential equations are calculated using automatic differentiation; then, the physical constraints are embedded into the loss function of the neural network architecture through physical equations; subsequently, the partial derivatives are integrated with the loss function to form a total loss function. The physical equations include, but are not limited to, two-dimensional Navier-Stokes equations, continuity equation, and turbulence model.

In this embodiment, the physical equations used to describe the wind field are first determined to reflect relationships among variables such as wind speed, wind direction, and air pressure. Based on the requirements of a physical model, a corresponding PINN architecture is then designed. The physical constraints and the loss function are embedded into the PINN architecture.

Specifically, the physical equations used to describe the wind field are first determined. Subsequently, based on the requirements of the physical model, the PINN architecture is designed. The PINN architecture includes an input layer, hidden layers, and an output layer. The input layer receives data of the two-dimensional velocity field. The hidden layers include an adequate number of neurons and layers to capture a nonlinear relationship in the wind speed data. The output layer outputs a predicted wind speed value. Furthermore, during a training process of the PINN architecture, the physical constraints or the loss function are embedded into the PINN architecture by defining physics-informed error terms. The physical constraints may be based on residuals of the physical equations or a data-driven loss function, ensuring that a predicted value output by the PINN architecture complies with the underlying physical laws.

For example, an input and an output of the model are first defined. In this embodiment, for a two-dimensional velocity field, the input includes two-dimensional grid data of the velocity field (such as velocity vector components in x and y directions). The output includes the predicted value of the velocity field and physical quantities such as velocity field features. Next, the PINN architecture is designed by employing a deep neural network as a nonlinear function approximator. By leveraging automatic differentiation, which is widely used in deep neural networks, the differential form of constraints in the partial differential equations to be solved is incorporated into the loss function of the neural network for optimization. Thus, the deep neural network model is trained to approximate the solutions of the partial differential equations under physical model constraints. Subsequently, weights and biases of the neural network of the PINN are initialized using a random initialization strategy. Then, the physical constraints that the velocity field must satisfy are identified, and the physical constraints are embedded into the loss function of the neural network using the physical equations. By combining the partial derivatives of the partial differential equations with the loss function, the total loss function is constructed.

Furthermore, the total loss function includes two parts: a data fitting loss term and a physics-based loss term. The data fitting loss term measures a discrepancy between the predicted value of the model and an actual observed value, such as mean squared error. The physics-based loss term penalizes predictions that violate the physical constraints, typically by quantifying a degree of violation as a penalty term and incorporating it into the loss function.

The physical equations are calculated as follows:

$$\frac{\partial u}{\partial t} + u \frac{\partial u}{\partial x} + v \frac{\partial u}{\partial y} = - \frac{1}{ρ} \frac{\partial p}{\partial x} + v ( \frac{{\partial }^{2} u}{\partial {x}^{2}} + \frac{{\partial }^{2} u}{\partial {y}^{2}} ) \qquad ( 1 )$$

$$\frac{\partial v}{\partial t} + u \frac{\partial v}{\partial x} + v \frac{\partial v}{\partial y} = - \frac{1}{ρ} \frac{\partial p}{\partial y} + v ( \frac{{\partial }^{2} v}{\partial {x}^{2}} + \frac{{\partial }^{2} v}{\partial {y}^{2}} ) \qquad ( 2 )$$

$$\frac{\partial u}{\partial x} + \frac{\partial v}{\partial y} = 0 \qquad ( 3 )$$

where ρ denotes a fluid density; u, v denote measured velocity components of a fluid at a location (x, y) and at a time t.

The total loss function is calculated as follows:

$$L = {ω}_{1} {L}_{d} + {ω}_{2} {L}_{f} \qquad ( 4 )$$

$${L}_{d} = {u}_{MRMSE} + {v}_{MRMSE} \qquad ( 5 )$$

$${u}_{MRMSE} = \frac{1}{{N}_{T}} {\sum }_{i = 1}^{{N}_{t}} ( \sqrt{\frac{1}{n} {\sum }_{i = 1}^{n} {( {\hat{u}}_{i} ( t ) - {u}_{i} ( t ) )}^{2}} ) \qquad ( 6 )$$

$${v}_{MRMSE} = \frac{1}{{N}_{T}} {\sum }_{i = 1}^{{N}_{t}} ( \sqrt{\frac{1}{n} {\sum }_{i = 1}^{n} {( {\hat{v}}_{i} ( t ) - {v}_{i} ( t ) )}^{2}} ) \qquad ( 7 )$$

$${L}_{f} = \frac{1}{{N}_{f}} {\sum }_{i = 1}^{{N}_{f}} {\vert G ( {u}_{i} , {p}_{i} ) \vert}^{2} \qquad ( 8 )$$

where L denotes the total loss function; L_{d} denotes a data fitting loss term; L_{f} denotes a physics-based loss term, i.e., a PDE residual loss; ω₁ denotes a weight of a data item; ω₂ denotes a weight of a physics-based loss term; n denotes a total number of laser sensors; N_{T} denotes a total number of time steps; u, v denote measured velocity components of a fluid at a location (x, y) and at a time t, i.e., measured values of the location; û, \hat{v} denote predicted velocity components of a fluid at a location (x, y) and at a time t; MRMSE denotes an average root mean square error; and G denotes an implicit form of Navier-Stokes equations.

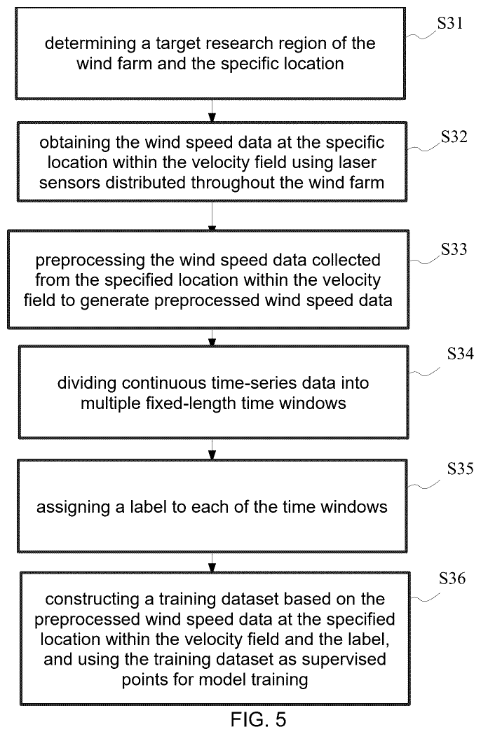

S3, obtaining wind speed data at a specific location within the velocity field based on the physics-informed neural network model, and constructing a training dataset. Please refer to FIG. 5. FIG. 5 is a flowchart of step S3 of a method for wind speed prediction and layout optimization in wind power generation according to the present application. As shown in FIG. 5, step S3 includes the following sub-steps.

Sub-step S31, determining a target research region of the wind farm and the specific location within the velocity field.

Sub-step S32, obtaining the wind speed data at the specific location within the velocity field using laser sensors distributed throughout the wind farm.

Sub-step S33, preprocessing the wind speed data collected from the specified location within the velocity field to generate preprocessed wind speed data at the specific location within the velocity field.

Sub-step S34, dividing continuous time-series data into multiple fixed-length time windows.

Sub-step S35, assigning a label to each of the time windows.

Sub-step S36, constructing a training dataset based on the preprocessed wind speed data at the specified location within the velocity field and the label, and using the dataset as supervised points for model training.

In this embodiment, the target research region of the wind farm and the specific location within the velocity field are first identified. The target research region includes, but is not limited to, geographical location, seabed topography, and surrounding environment. The specific location refers to a position such as a foundation of a wind turbine, a boundary of the wind farm, or a region possessing special physical characteristics.

Then, historical wind speed data, meteorological data (such as wind direction, temperature, humidity, air pressure, and altitude), and physical parameters (such as terrain elevation, ocean current fields, and temperature gradients) at the specified location and its surrounding area are collected using the laser sensors deployed within the wind farm.

Next, the wind speed data at the specific location within the velocity field are cleaned by removing outliers, missing values, and invalid data points to ensure data quality, thereby obtaining the preprocessed wind speed data at the specific location within the velocity field.

Subsequently, the continuous time-series data is divided into multiple fixed-length time windows. Each of the time windows includes data from multiple time steps, which are used to predict wind speed at one or more future time steps. Then, each time window is assigned a label corresponding to the future wind speed at one or more time steps following the time window. Finally, based on the preprocessed wind speed data at the specific location within the velocity field and the label, training, validation, and test datasets are constructed to facilitate cross-validation during training and final evaluation of the model.

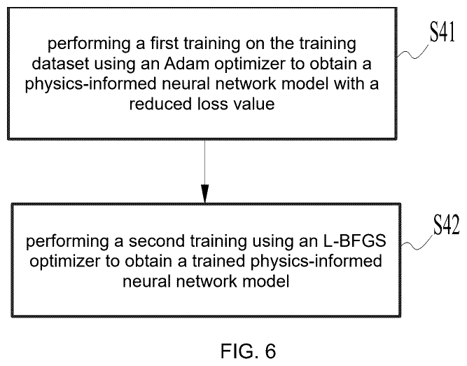

S4, training the physics-informed neural network model based on the training dataset. Refer to FIG. 6. FIG. 6 is a flowchart of step S4 of a method for wind speed prediction and layout optimization in wind power generation according to the present application. As shown in FIG. 6, step S4 includes the following sub-steps.

Sub-step S41, performing a first training on the training dataset using an Adam optimizer to obtain a physics-informed neural network model with a reduced loss value.

In this embodiment, the weights and the biases of the neural network are first initialized. Then, parameters of the Adam optimizer are configured. Subsequently, the physics-informed neural network model is trained using samples from the training dataset.

Specifically, the training dataset is iteratively processed, with each iteration including four steps: forward propagation, loss calculation, backpropagation, and parameter update.

In the forward propagation step, a predicted value of the model is calculated based on a given input.

In the loss computation step, a composite loss function incorporating physical constraints is used to evaluate a difference between the predicted value and an actual value.

In the backpropagation step, the weights and biases of the model are updated based on gradient information of the loss function.

The Adam optimizer is employed to adaptively adjust a learning rate according to the gradient information and to update model parameters.

It should be noted that during the training process, the changes in the loss function should be regularly monitored to ensure a gradual decrease in loss values. Meanwhile, the validation dataset can be used to assess the model's generalization capability and to prevent overfitting or underfitting.

Sub-step S42, performing a second training using an L-BFGS optimizer until a convergence condition is satisfied, thereby obtaining a trained physics-informed neural network model.

In this embodiment, parameters of the L-BFGS optimizer and a maximum number of iterations are first adjusted as needed. The L-BFGS optimizer is then configured and used for training.

Specifically, the L-BFGS optimizer is configured within a deep learning framework, and an optimization closure function is prepared, which computes the loss and returns gradients. The L-BFGS optimizer then performs iterative optimization until the convergence condition is satisfied (such as a value of the total loss function is less than a preset threshold). During each iteration, the L-BFGS optimizer automatically adjusts a step size and updates the weights and biases of the neural network in an optimal direction. After each iteration, the convergence condition is checked; if satisfied, the training stops; otherwise, the next iteration proceeds. Finally, the trained model may be tested and evaluated using the test dataset.

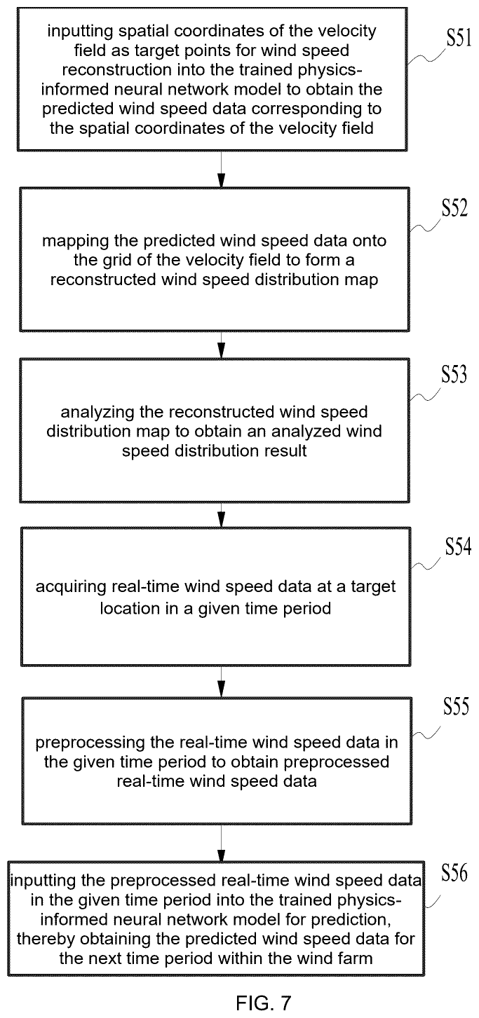

S5, reconstructing a wind speed distribution within the velocity field and obtaining predicted wind speed data for a next time period within the wind farm using the trained physics-informed neural network model. Refer to FIG. 7. FIG. 7 is a flowchart of step S5 of a method for wind speed prediction and layout optimization in wind speed generation according to the present application. As shown in FIG. 7, step S5 includes the following sub-steps.

Sub-step S51, inputting spatial coordinates of the velocity field as target points for wind speed reconstruction into the trained physics-informed neural network model to obtain the predicted wind speed data corresponding to the spatial coordinates of the velocity field.

Sub-step S52, mapping the predicted wind speed data onto the grid of the velocity field to form a reconstructed wind speed distribution map.

Sub-step S53, analyzing the reconstructed wind speed distribution map to obtain an analyzed wind speed distribution result, and performing optimization and fine-tuning on the trained physics-informed neural network model accordingly.

Sub-step S54, acquiring real-time wind speed data at a target location in a given time period.

Sub-step S55, preprocessing the real-time wind speed data in the given time period to obtain preprocessed real-time wind speed data.

Sub-step S56, inputting the preprocessed real-time wind speed data in the given time period into the trained physics-informed neural network model for prediction, thereby obtaining the predicted wind speed data for the next time period within the wind farm.

In this embodiment, the spatial coordinates of the velocity field are first used as the target points for wind speed reconstruction and input into the trained physics-informed neural network model. The trained physics-informed neural network model performs the forward propagation based on the input data and outputs the predicted wind speed data corresponding to respective locations. The predicted wind speed data reflect the wind speed distribution at various points within the velocity field. Next, the predicted wind speed data are mapped onto the grid of the velocity field to form the reconstructed wind speed distribution map. Subsequently, the reconstructed wind speed distribution map is analyzed to verify whether it conforms to physical laws and actual observations. If a deviation or inconsistency with real conditions is found, the trained physics-informed neural network model can be fine-tuned or retrained to improve the accuracy of the wind speed reconstruction. Meanwhile, the model's input data, network structure, parameter settings, and other aspects may be optimized based on the reconstruction result to further enhance model performance.

Furthermore, the real-time wind speed data at the target location in the given time period is acquired. The real-time wind speed data in the given time period is then cleaned and normalized. The processed real-time wind speed data is input into the trained physics-informed neural network model, and a prediction time range is set to output the predicted wind speed data in the time range. Finally, error metrics, such as mean squared error (MSE) or mean absolute error (MAE), are used to quantify the prediction performance. Based on an evaluation result, the model parameters are adjusted to improve prediction accuracy.

S6, optimizing a layout of a wind turbine cluster based on the reconstructed wind speed distribution within the velocity field.

In this embodiment, a wind turbine control strategy is formulated based on the predicted wind speed data, and then is applied to wind turbines for real-time adjustment via a control system.

Specifically, the wind turbine control strategy is developed based on the predicted wind speed data combined with the actual conditions of the wind farm, such as turbine types, quantity, and layout. The wind turbine control strategy includes, but is not limited to, adjusting parameters such as the turbine's power output, blade pitch angle, and rotational speed to maximize the wind farm's power generation efficiency and reduce wear and tear. Subsequently, the formulated wind turbine control strategy is implemented in the wind farm, where the turbines are adjusted in real time through the control system. An operational status of the wind farm after implementing the wind turbine control strategy, including power generation and turbine conditions, is monitored. Based on a monitoring result, the wind turbine control strategy is evaluated and adjusted to continuously optimize the operational efficiency of the wind farm.

It should be noted that the data used for training in the present application is provided by coherent Doppler wind lidars deployed throughout the wind farm. The coherent Doppler wind lidars employ single-frequency narrow-linewidth lasers to emit laser pulses, which interact with aerosol particles in the atmosphere to generate echo signals containing Doppler frequency shifts. The atmospheric echo signals collected by a telescope system are coherently mixed with intrinsic laser signals to extract Doppler frequency shift information. Three-dimensional atmospheric wind field information is then obtained through vector wind velocity inversion techniques. Mesoscale numerical simulation results are used as the supervised points for training the PINN. Although mesoscale numerical simulation can fit characteristics such as airflow, air pressure, and wind fields over a large area, it cannot accurately assess local wind flow conditions within the wind farm. By incorporating fluid dynamics governing equations into the loss function, similarly to CFD principles, the PINN achieves precise microscale simulations of an internal area of the wind farm. Finally, the data observed by the coherent Doppler wind lidars and the numerical simulation results of the PINN are combined to improve evaluation accuracy and better reflect the actual wind field conditions.

The PINN realizes physical constraints by embedding physical information, such as physical equations, boundary conditions, or initial conditions, into the loss function. During training, appropriate weights are selected to minimize the loss function, thereby obtaining a model that yields low error relative to actual values while satisfying physical laws. The trained model produces wind speed data at the specific location for next time period. Ultimately, the wind turbine control strategy is optimized to provide support for an intelligent operation and maintenance of the wind farm. Moreover, flow field reconstruction based on measured data enables further study on how turbine layout affects wind farm power generation efficiency.

Additionally, the PINN-based reconstruction is performed using the two-dimensional wind velocity distribution. Subsequently, multiple neural networks may be constructed at different elevation layers to more accurately and comprehensively represent the three-dimensional wind field.

The following illustrates an example of a wind speed prediction process for a wind farm located within a specific region.

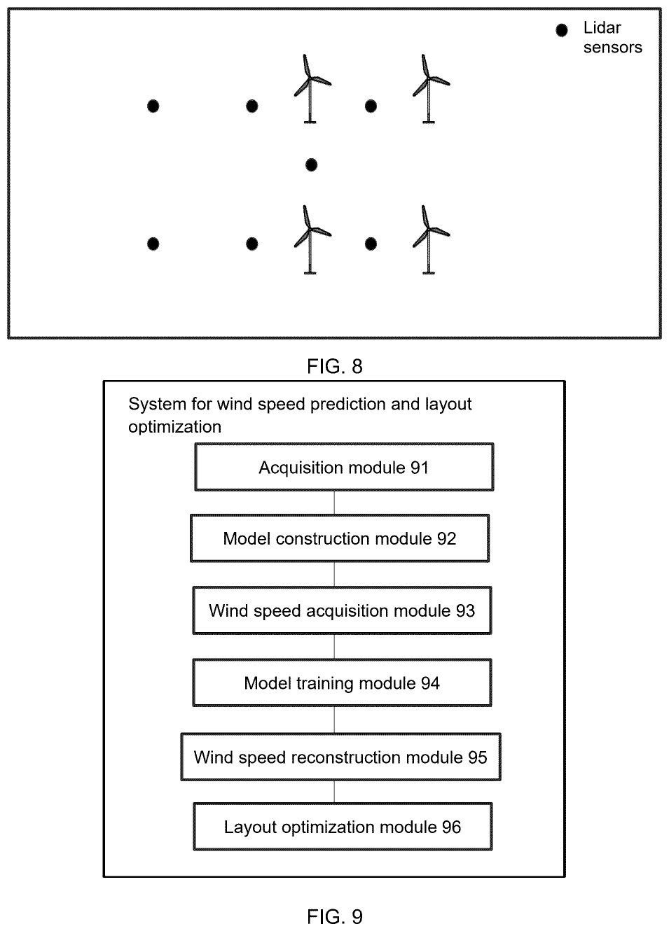

Please refer to FIG. 8. FIG. 8 is a layout of laser sensors and wind turbines in a wind farm of a method for wind speed prediction and layout optimization according to an embodiment of the present application.

First, lidar sensors are arranged at specified distances upstream and downstream of the wind turbines within the region to monitor local wind speeds and pressure distributions. These measurements serve as supervised points for training the neural network.

Next, a feedforward neural network is constructed with the two-dimensional velocity field defining the domain. The neural network takes spatial coordinates (horizontal coordinate x, vertical coordinate y) and temporal parameter t as inputs, and outputs velocity components (horizontal component u, vertical component v) and pressure p. A domain size is set according to the size of the wind farm. For example, considering a wind farm including multiple 15 MW wind turbines, each with a hub height of 150 m and a rotor diameter of 242 m, the domain size can be set to 10.6 km×4 km.

The partial derivatives required for calculating the residuals of the partial differential equations are subsequently obtained through automatic differentiation.

Subsequently, physical constraints are incorporated to construct the physics-informed neural network. In the present application, the physical equations refer to two-dimensional Navier-Stokes equations, continuity equation, and turbulence model.

The physical equations are calculated as follows:

$$\frac{\partial u}{\partial t} + u \frac{\partial u}{\partial x} + v \frac{\partial u}{\partial y} = - \frac{1}{ρ} \frac{\partial p}{\partial x} + v ( \frac{{\partial }^{2} u}{\partial {x}^{2}} + \frac{{\partial }^{2} u}{\partial {y}^{2}} ) \\ \frac{\partial v}{\partial t} + u \frac{\partial v}{\partial x} + v \frac{\partial v}{\partial y} = - \frac{1}{ρ} \frac{\partial p}{\partial y} + v ( \frac{{\partial }^{2} v}{\partial {x}^{2}} + \frac{{\partial }^{2} v}{\partial {y}^{2}} ) \\ \frac{\partial u}{\partial x} + \frac{\partial v}{\partial y} = 0$$

where ρ denotes a fluid density; u, v denote measured velocity components of a fluid at a point (x, y) and at a time t.

Then, a partial derivative residual loss is combined with the data fitting loss term to obtain a total loss.

That is, the total loss function is calculated as follows:

$$L = {ω}_{1} {L}_{d} + {ω}_{2} {L}_{f} \\ {L}_{d} = {u}_{MRMSE} + {v}_{MRMSE} \\ {u}_{MRMSE} = \frac{1}{{N}_{T}} {\sum }_{i = 1}^{{N}_{t}} ( \sqrt{\frac{1}{n} {\sum }_{i = 1}^{n} {( {\hat{u}}_{i} ( t ) - {u}_{i} ( t ) )}^{2}} ) \\ {v}_{MRMSE} = \frac{1}{{N}_{T}} {\sum }_{i = 1}^{{N}_{t}} ( \sqrt{\frac{1}{n} {\sum }_{i = 1}^{n} {( {\hat{v}}_{i} ( t ) - {v}_{i} ( t ) )}^{2}} ) \\ {L}_{f} = \frac{1}{{N}_{f}} {\sum }_{i = 1}^{{N}_{f}} {\vert G ( {u}_{i} , {p}_{i} ) \vert}^{2}$$

where L denotes the total loss function; L_{d} denotes a data fitting loss term; L_{f} denotes a physics-based loss term, i.e., a PDE residual loss; ω₁ denotes a weight of a data item; ω₂ denotes a weight of a physics-based loss term; n denotes a total number of laser sensors; N_{T} denotes a total number of time steps; u, v denote measured velocity components of a fluid at a location (x, y) and at a time t, i.e., measured values of the location; û, \hat{v} denote predicted velocity components of a fluid at a location (x, y) and at a time t; MRMSE denotes an average root mean square error; and G denotes an implicit form of Navier-Stokes equations.

Next, the neural network is trained by continuously updating the weights and biases until the total loss function satisfies a predetermined criterion (e.g., less than a preset threshold). The model is first trained using the Adam optimizer to achieve a rapid reduction in the loss value, followed by training with the L-BFGS optimizer until convergence.

Based on the trained model, the two-dimensional velocity field can be reconstructed, enabling fast prediction of an effective wind speed at a wind turbine rotor within a short-term period.

Finally, based on predicted wind speed variation for the next time period, wind turbine control optimization can be realized.

The method for wind speed prediction and layout optimization of the present application simulates the wind speed distribution within the velocity field by utilizing lidar sensors deployed throughout the wind farm. Based on measured data, the method more accurately reflects actual operating conditions. It predicts wind speed changes at turbine locations for the next time period, providing a reference for analyzing wind power generation patterns and enabling a more comprehensive understanding of the wind farm's physical characteristics. By combining mesoscale numerical simulations from lidar measurements with microscale numerical simulations using the PINN, the accuracy of wind field assessment is improved. At the same time, integrating machine learning techniques with extensive fluid dynamics data provides accurate velocity field predictions with relatively high computational efficiency. Similarly, the present application can accurately reconstruct regional flow using only a limited number of flow field sampling data points. The PINN model is suitable for wind farm modeling, providing accurate, ultra-short-term velocity field predictions while maintaining computational efficiency. This supports short-term control adjustments such as pitch and yaw regulation, thereby ensuring the safe and stable operation of the wind farm.

The scope of protection for the wind speed prediction and layout optimization method described in the present embodiment is not limited to the order of the steps listed. Any solutions formed by adding, deleting, or substituting steps in the prior art based on the principles of the present application are encompassed within the scope of protection of the present application.

A second embodiment of the present application provides a system for wind speed prediction and layout optimization. The system can implement the method for wind speed prediction and layout optimization described above. However, the device for implementing the method of the present application is not limited to the structure of the system described in this embodiment. Any structural modifications or substitutions made to the prior art based on the principles of the present application are intended to fall within the scope of protection of the present application.

The following description will provide a detailed illustration of a wind speed prediction and layout optimization system according to this embodiment, in conjunction with the accompanying drawings.

The system for wind speed prediction and layout optimization is provided.

Refer to FIG. 9. FIG. 9 is a schematic structural diagram of a system for wind speed prediction and layout optimization according to an embodiment of the present application. As shown in FIG. 9, the system includes an acquisition module 91, a model construction module 92, a wind speed acquisition module 93, a model training module 94, a wind speed reconstruction module 95, and an optimization layout module 96.

The acquisition module 91 obtains a basic wind resource dataset of a target region, including one or more data of wind farm size, location information, wind speed, wind direction, temperature, air pressure, terrain, and water depth.

In this embodiment, various types of data and information within a wind farm are collected from a target region based on research needs, including location information, meteorological data, terrain data, and the like, to obtain the basic wind resource dataset.

Specifically, a scope of the target region for data acquisition is first determined. Then, data sources are identified, such as official or authoritative organizations (such as national or local government energy departments, meteorological bureaus, oceanographic institutes, research institutions, and commercial data providers), from which relevant data is obtained through their respective channels. Finally, the acquired data is collected, compiled, and organized.

The model construction module 92 is connected to the acquisition module 91 and is configured to construct a physics-informed neural network model based on the basic wind resource dataset.

In this embodiment, an actual wind farm size is extracted based on the basic wind resource dataset, and a two-dimensional velocity field is defined according to the actual wind farm size.

Wind speed data is selected from the basic wind resource dataset and preprocessed to obtain preprocessed wind speed data. In combination with a two-dimensional grid defined based on the actual wind farm size, a wind field is simulated using the two-dimensional grid to generate a two-dimensional velocity field. A neural network architecture is designed based on the two-dimensional velocity field, and a physics-informed neural network model is constructed by incorporating physical constraints into a loss function of the neural network architecture for optimization. This step further includes the following sub-steps: first, partial derivatives of partial differential equations are calculated using automatic differentiation; then, the physical constraints are embedded into the loss function of the neural network architecture through physical equations; subsequently, the partial derivatives are integrated with the loss function to form a total loss function. The physical equations include, but are not limited to, two-dimensional Navier-Stokes equations, continuity equation, and turbulence model.

In this embodiment, the wind speed data is selected from the basic wind resource dataset and preprocessed to obtain the preprocessed wind speed data. In combination with the two-dimensional grid defined based on the actual wind farm size, the wind field is simulated using the two-dimensional grid to generate the two-dimensional velocity field. The physical equations used to describe the wind field are first determined to reflect relationships among variables such as wind speed, wind direction, and air pressure. Based on the requirements of a physical model, a corresponding PINN architecture is then designed. The physical constraints and the loss function are embedded into the PINN architecture.

Specifically, the physical equations used to describe the wind field are first determined. Subsequently, based on the requirements of the physical model, the PINN architecture is designed. The PINN architecture includes an input layer, hidden layers, and an output layer. The input layer receives data of the two-dimensional velocity field. The hidden layers include an adequate number of neurons and layers to capture a nonlinear relationship in the wind speed data. The output layer outputs a predicted wind speed value. Furthermore, during a training process of the PINN architecture, the physical constraints or the loss function are embedded into the PINN architecture by defining physics-informed error terms. The physical constraints may be based on residuals of the physical equations or a data-driven loss function, ensuring that a predicted value output by the PINN architecture complies with the underlying physical laws.

The wind speed acquisition 93 module obtains wind speed data at a specific location in a velocity field based on the physics-informed neural network model, and constructs a training dataset.

In this embodiment, a target research region of the wind farm and the specific location within the velocity field are determined. The wind speed data at the specific location within the velocity field are obtained using laser sensors distributed throughout the wind farm. The wind speed data collected from the specified location within the velocity field is preprocessed to generate preprocessed wind speed data. Continuous time-series data is divided into multiple fixed-length time windows. A label is assigned to each of the time windows. A training dataset is constructed based on the preprocessed wind speed data at the specified location within the velocity field and the label, and is used as supervision points for model training.

The model training module 94 trains the physics-informed neural network model based on the training dataset.

In this embodiment, a first training is performed on the training dataset using an Adams optimizer to obtain a physics-informed neural network model with a reduced loss value. A second training is performed using an L-BFGS optimizer until a convergence condition is satisfied, thereby obtaining a trained physics-informed neural network model.

In this embodiment, the weights and the biases of the neural network are first initialized. Then, parameters of the Adam optimizer are configured. Subsequently, the physics-informed neural network model is trained using samples from the training dataset. Parameters of the L-BFGS optimizer and a maximum number of iterations are first adjusted as needed. The L-BFGS optimizer is then configured and used for training.

Specifically, the training dataset is iteratively processed, with each iteration including four steps: forward propagation, loss calculation, backpropagation, and parameter update. In the forward propagation step, the predicted value of the model is calculated based on a given input. In the loss computation step, a composite loss function incorporating physical constraints is used to evaluate a difference between the predicted value and an actual value. In the backpropagation step, the weights and biases of the model are updated based on gradient information of the loss function. The Adam optimizer is employed to adaptively adjust a learning rate according to the gradient information and to update model parameters.

Specifically, the L-BFGS optimizer is configured within a deep learning framework, and an optimization closure function is prepared, which computes the loss and returns gradients. The L-BFGS optimizer then performs iterative optimization until the convergence condition is satisfied (such as a value of the total loss function is less than a preset threshold). During each iteration, the L-BFGS optimizer automatically adjusts a step size and updates the weights and biases of the neural network in an optimal direction. After each iteration, the convergence condition is checked; if satisfied, the training stops; otherwise, the next iteration proceeds. Finally, the trained model may be tested and evaluated using a test dataset.

The wind speed reconstruction module 95 reconstructs a wind speed distribution in the velocity field through the trained physics-informed neural network model, and obtains a predicted wind speed for a next time period within a wind farm.

In this embodiment, spatial coordinates of the velocity field are first used as the target points for wind speed reconstruction and input into the trained physics-informed neural network model to obtain the predicted wind speed data corresponding to the spatial coordinates of the velocity field. The predicted wind speed data are mapped onto the grid of the velocity field to form a reconstructed wind speed distribution map. The reconstructed wind speed distribution map is analyzed to obtain an analyzed wind speed distribution result, and the trained physics-informed neural network model is optimized and fine-tuned. Real-time wind speed data at a target location in a given time period is obtained. The real-time wind speed data in the given time period is preprocessed to obtain preprocessed real-time wind speed data. The preprocessed real-time wind speed data in the given time period is input into the trained physics-informed neural network model for prediction, thereby obtaining the predicted wind speed data for the wind farm for the next time period.

The layout optimization module 96 optimizes a layout of wind turbine cluster based on a reconstructed wind speed distribution within the velocity field.

In this embodiment, a wind turbine control strategy is formulated based on the predicted wind speed data, and then is applied to wind turbines for real-time adjustment via a control system.

The system for wind speed prediction and layout optimization, established based on a model for wind speed prediction of wind power generation and layout optimization, effectively utilizes big data combined with machine learning techniques to efficiently predict wind speed distribution within the wind farm, thereby offering valuable guidance for its efficient operation and maintenance.

It should be understood that the division of the various modules of the above system is merely a logical functional partition. In actual implementation, these modules may be fully or partially integrated into a single physical entity, or physically separated. Furthermore, these modules may be implemented entirely in software executed by processing components, entirely in hardware, or partially by software called by processing components and partially in hardware. For example, an x may be implemented as a standalone processing component, integrated within a chip of the aforementioned system, or stored as program code in a memory of the system and invoked and executed by a processing component of the system to perform the functions of module. Implementation of other modules is similar. Additionally, these modules may be fully or partially integrated together or implemented independently. The processing component described herein may be an integrated circuit with signal processing capabilities. During implementation, the steps of the method or the respective modules may be accomplished by hardware-integrated logic circuits in a processor component or by software instructions.

The above modules may be configured as one or more integrated circuits that implement the above methods, such as one or more application-specific integrated circuits (ASICs), one or more digital signal processors (DSPs), one or more field-programmable gate arrays (FPGAs), or the like. Alternatively, when any of the above modules is implemented by a processing component executing program code, the processing component may be a general-purpose processor, such as a central processing unit (CPU) or other processors capable of executing program code. Furthermore, these modules may be integrated together and implemented in the form of a system-on-a-chip (SoC).

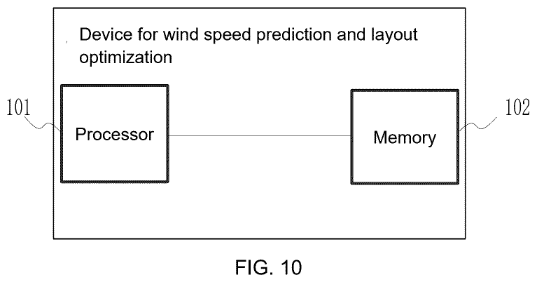

Please refer to FIG. 10. FIG. 10 is a schematic structural diagram of a device for wind speed prediction and layout optimization according to an embodiment of the present application. As shown in FIG. 10, this embodiment provides a device for wind speed prediction and layout optimization. The device includes a processor 101 and a memory 102. The memory 102 is configured to store computer programs. The processor 101 is connected to the memory 102 and configured to execute the computer programs stored in the memory 102, thereby causing the device to perform each step of the method for wind speed prediction and layout optimization described above.

Preferably, the memory may include a random access memory (RAM), and may further include a non-volatile memory, such as at least one disk storage device.

The above processor may be a general-purpose processor, including but not limited to a central processing unit (CPU), a network processor (NP); alternatively, it may be a digital signal processor (DSP), an application-specific integrated circuit (ASIC), a field programmable gate array (FPGA), or other programmable logic devices, discrete gate or transistor logic devices, or discrete hardware components.

In summary, the method, system, and device for wind speed prediction and layout optimization provided in wind power generation of the present application have the following beneficial effects.

The wind speed prediction and layout optimization method of the present application simulates the wind speed distribution within the velocity field by utilizing lidar sensors deployed throughout the wind farm. Based on measured data, the present application more accurately reflects actual operating conditions. It predicts wind speed changes at turbine locations for the next time period, providing a reference for analyzing wind power generation patterns and enabling a more comprehensive understanding of the wind farm's physical characteristics. By combining mesoscale numerical simulations from lidar measurements with microscale numerical simulations using the PINN, the accuracy of wind field assessment is improved. At the same time, integrating machine learning techniques with extensive fluid dynamics data provides accurate velocity field predictions with relatively high computational efficiency. Similarly, the present application can accurately reconstruct regional flow using only a limited number of flow field sampling data points. The PINN model is suitable for wind farm modeling, providing accurate, ultra-short-term velocity field predictions while maintaining computational efficiency. This supports short-term control adjustments such as pitch and yaw regulation, thereby ensuring the safe and stable operation of the wind farm.

The embodiments described above serve merely as illustrative examples of the principles and effects of the present application, and are not intended to serve as limitations on the present application. Persons skilled in the art may modify or alter these embodiments without departing from the spirit and scope of the present application. Therefore, any equivalent modifications or alterations made by those skilled in the art, which are consistent with the spirit and technical concepts disclosed in the present application, shall still fall within the scope of the claims of the present application.

1. A method for wind speed prediction and layout optimization in wind power generation, comprising:
obtaining a basic wind resource dataset of a target region, comprising one or more of wind farm size, location information, wind speed, wind direction, temperature, air pressure, terrain, and water depth;
constructing a physics-informed neural network model based on the basic wind resource dataset;
obtaining a wind speed at a specific location in a velocity field based on the physics-informed neural network model and constructing a training dataset;
training the physics-informed neural network model based on the training dataset;
reconstructing a wind speed distribution within the velocity field and obtaining predicted wind speed data for a next time period with a wind farm using a trained physics-informed neural network model; and
optimizing a layout of a wind turbine cluster based on a reconstructed wind speed distribution within the velocity field.

2. The method according to claim 1, wherein a method for constructing the physics-informed neural network model based on the basic wind resource dataset comprises steps of:
extracting an actual wind farm size based on the basic wind resource dataset;
defining a two-dimensional velocity field based on the actual wind farm size;
designing a neural network architecture based on the two-dimensional velocity field; and
constructing the physics-informed neural network model by incorporating physical constraints into a loss function of the neural network architecture for optimization.

3. The method according to claim 2, wherein a method for incorporating the physical constraints into the loss function of the neural network architecture for optimization comprises steps of:
calculating partial derivatives of partial differential equations using automatic differentiation;
integrating the physical constraints into the loss function of the neural network architecture using physical equations; and
obtaining a total loss function by combining the partial derivatives of the partial differential equations with the loss function.

4. The method according to claim 3, wherein the physical equations comprise two-dimensional Navier-Stokes equations, continuity equation, and turbulence model;
wherein the physical equations are calculated as follows:
$$\frac{\partial u}{\partial t} + u \frac{\partial u}{\partial x} + v \frac{\partial u}{\partial y} = - \frac{1}{ρ} \frac{\partial p}{\partial x} + v ( \frac{{\partial }^{2} u}{\partial {x}^{2}} + \frac{{\partial }^{2} u}{\partial {y}^{2}} ) \\ \frac{\partial v}{\partial t} + u \frac{\partial v}{\partial x} + v \frac{\partial v}{\partial y} = - \frac{1}{ρ} \frac{\partial p}{\partial y} + v ( \frac{{\partial }^{2} v}{\partial {x}^{2}} + \frac{{\partial }^{2} v}{\partial {y}^{2}} ) \\ \frac{\partial u}{\partial x} + \frac{\partial v}{\partial y} = 0$$
wherein ρ denotes a fluid density; u, v denote measured velocity components of a fluid at a point (x, y) and at a time t.

5. The method according to claim 3, wherein the total loss function is calculated as follows:
$$L = {ω}_{1} {L}_{d} + {ω}_{2} {L}_{f} \\ {L}_{d} = {u}_{MRMSE} + {v}_{MRMSE} \\ {u}_{MRMSE} = \frac{1}{{N}_{T}} {\sum }_{i = 1}^{{N}_{t}} ( \sqrt{\frac{1}{n} {\sum }_{i = 1}^{n} {( {\hat{u}}_{i} ( t ) - {u}_{i} ( t ) )}^{2}} ) \\ {v}_{MRMSE} = \frac{1}{{N}_{T}} {\sum }_{i = 1}^{{N}_{t}} ( \sqrt{\frac{1}{n} {\sum }_{i = 1}^{n} {( {\hat{v}}_{i} ( t ) - {v}_{i} ( t ) )}^{2}} ) \\ {L}_{f} = \frac{1}{{N}_{f}} {\sum }_{i = 1}^{{N}_{f}} {\vert G ( {u}_{i} , {p}_{i} ) \vert}^{2}$$
where L denotes the total loss function; L_{d} denotes a data fitting loss term; L_{f} denotes a physics-based loss term, i.e., a PDE residual loss; ω₁ denotes a weight of a data fitting loss term; ω₂ denotes a weight of a physics-based loss term; n denotes a total number of laser sensors; N_{T} denotes a total number of time steps; u, v denote measured velocity components of a fluid at a location (x, y) and at a time t, i.e., measured values of the location; û, \hat{v} denote predicted velocity components of a fluid at a location (x, y) and at a time t; MRMSE denotes an average root mean square error; and G denotes an implicit form of Navier-Stokes equations.

6. The method according to claim 1, wherein a method for obtaining the wind speed data at the specific location in the velocity field based on the physics-informed neural network model, and constructing the training dataset comprises steps of:
determining a target research region of the wind farm and the specific location;
obtaining the wind speed data at the specific location within the velocity field using laser sensors distributed throughout the wind farm;
preprocessing the wind speed data collected from the specified location within the velocity field to generate preprocessed wind speed data;
dividing continuous time-series data into a plurality of fixed-length time windows;
assigning a label to each of the plurality of time windows; and
constructing a training dataset based on the preprocessed wind speed data at the specified location within the velocity field and the label, and using the training dataset as supervised points for model training.

7. The method according to claim 1, wherein a method for training the physics-informed neural network model based on the training dataset comprises steps of:
performing a first training on the training dataset using an Adam optimizer to obtain a physics-informed neural network model with a reduced loss value;
performing a second training using an L-BFGS optimizer until a convergence condition is satisfied, thereby obtaining the trained physics-informed neural network model.

8. The method according to claim 1, wherein performing the second training using the L-BFGS optimizer until the convergence condition is satisfied, thereby obtaining the trained physics-informed neural network model comprises steps of:
inputting spatial coordinates of the velocity field as target points for wind speed reconstruction into the trained physics-informed neural network model to obtain the predicted wind speed data corresponding to the spatial coordinates of the velocity field;
mapping the predicted wind speed data onto grid of the velocity field to form a reconstructed wind speed distribution map;
analyzing the reconstructed wind speed distribution map to obtain an analyzed wind speed distribution result, and performing optimization and fine-tuning on the trained physics-informed neural network model;
acquiring real-time wind speed data at a target location in a given time period;
preprocessing the real-time wind speed data in the given time period to obtain preprocessed real-time wind speed data; and
inputting the preprocessed real-time wind speed data in the given time period into the trained physics-informed neural network model for prediction, thereby obtaining the predicted wind speed data for the next time period with the wind farm.

9. A system for wind speed prediction and layout optimization in wind power generation, comprising:
an acquisition module configured to obtain a basic wind resource dataset of a target region, wherein the basic wind resource dataset comprises one or more of wind farm size, location information, wind speed, wind direction, temperature, air pressure, terrain, and water depth;
a model construction module configured to construct a physics-informed neural network model based on the basic wind resource dataset;
a wind speed acquisition module configured to obtain wind speed data at a specific location in a velocity field based on the physics-informed neural network model, and constructs a training dataset;
a model training module configured to train the physics-informed neural network model based on the training dataset;
a wind speed reconstruction module configured to reconstruct a wind speed distribution in the velocity field through a trained physics-informed neural network model, and obtain a predicted wind speed for a next time period within a wind farm; and
a layout optimization module configured to optimize a layout of a wind turbine cluster based on a reconstructed wind speed distribution within the velocity field.

10. A device for wind speed prediction and layout optimization in wind power generation, comprising a processor and a memory;
wherein the memory is configured to store computer programs;
wherein the processor is connected to the memory and configured to execute the computer programs stored in the memory so that the device can implement the method according to claim 1.
